(19) United States
(12) Patent Application Publication
(10) Pub. No.: US 2018/0040384 A1
(43) Pub. Date: Feb. 8, 2018

(54) MULTIPLE TEMPERATURE TESTING OF NON-VOLATILE MEMORY DATA RETENTION TIME

(71) Applicant: LINEAR TECHNOLOGY CORPORATION, Milpitas, CA (US)

(72) Inventors: Kalin V. LAZAROV, Colorado Springs, CO (US); Timothy D. ROHRER, Colorado Springs, CO (US); Michael D. Petersen, Elbert, CO (US)

(21) Appl. No.: 15/672,171

(22) Filed: Aug. 8, 2017

Related U.S. Application Data
(60) Provisional application No. 62/372,103, filed on Aug. 8, 2016.

(51) Int. Cl. G11C 29/50; G11C 16/34; G06F 11/30; G11C 7/04

(52) U.S. Cl. CPC G11C 29/50016; G11C 7/04; G11C 16/3418; G11C 16/3495; G06F 11/3037; G06F 11/3058

(57) ABSTRACT

The data retention time of a non-volatile memory array containing multiple non-volatile memory cells, each cell having a floating gate, may be tested. The method may include: baking the non-volatile memory array at a first temperature for a first duration and at a second temperature that is materially different than the first temperature for a second duration; testing the non-volatile memory array before and after each baking; and deciding whether to use or sell the tested non-volatile memory array based on results of the testing before and after each baking.

### CROSS-REFERENCE TO RELATED APPLICATION

This application is based upon and claims priority to U.S. provisional patent application 62/372,103, entitled “Method for Production Testing of Non-Volatile Memory Data Retention Time,” filed Aug. 8, 2016. The entire content of this application is incorporated herein by reference.

### BACKGROUND

### Technical Field

This disclosure relates to procedures for testing non-volatile memory arrays.

### Description of Related Art

Non-volatile memory arrays based on floating gate technology, such as EPROM, EEPROM and FLASH, store the information as a charge on a floating gate of a MOS transistor. With the passage of time, the charge dissipates, reducing the read margin, and eventually results in loss of data.

The primary mechanism for data retention failure may be charge loss in the floating gate, and the rate of charge loss may be accelerated by temperature. A data retention test may use this temperature acceleration to simulate the aging of the part by storing the memory at high temperature for a short period of time.

FIG. 1 illustrates an example of a temperature test for a non-volatile memory array.

Each floating gate in the memory array may be charged, as illustrated in a Charge Each Floating Gate in Memory Array step 101. This may be accomplished, for example, by setting each cell in the memory array to state that causes its floating gate(s) to be charged.

The memory array may then be baked for a predetermined time at a predetermined temperature, as illustrated by a Bake Memory Array step 103. This may be accomplished, for example, by placing the memory array in an oven.

The high-temperature bake may provide enough simulated aging to ensure that passing devices meet the datasheet specifications for retention.

After the baking is completed, each cell may be rested for a data error, as illustrated by a Test Each Cell for Data Error step 105. This may be accomplished, for example, by digitally reading the binary information stored in each floating gate to verify that it still contains the previously programmed value If it does not, this may indicate a data error in the cell.

A determination may then be made as to whether any cell in the array contained a data error, as reflected in an Any Data Error? decision step 107. If none of the cells contained a data error, the memory array may not be rejected, as reflected in a Do Not Reject Array step 109. On the other hand, if one or more errors were detected during the Test Each Cell for Data Error step 105, then the memory array may be rejected, as reflected in a Reject Array step 111.

This process can be simple and require only a digital readout. However, the process may not be capable of identifying all defective memory cells.

The simulated aging can be described by an acceleration factor A_{f}, which is a function of the activation energy of the cell E_{c}, the retention bake temperature and the temperature where the retention is specified in the datasheet, T₀:

$${A}_{f} = {e}^{( \frac{{qE}_{a}}{k} ) ( \frac{1}{{T}_{0}} - \frac{1}{{T}_{1}} )} \qquad ( 1 )$$

where the temperatures are in K, q is the electron charge, and k is Boltzmann's constant. For example, if the lowest activation energy for all cells in the array is assumed to be Eₐ=1.0 eV, the datasheet of the part specifies retention time at T₀=105° C., and the high-temperature bake is at T₁=250° C., the acceleration factor is A_{f}=4934. Under these conditions, a 48 hour bake at 250° C. is equivalent to 27 years at 105° C.

The problem with this approach is that the worst case activation energy is assumed to be known, in this example Eₐ=1.0 eV. However, in practice, there can be cell defects with significantly lower activation energies. For a defect with Eₐ=0.5 eV, for example, the bake acceleration factor for the same conditions may be only A_{f}=70. A 48 hour 250° C. bake may therefore be equivalent to only 0.4 years of data retention at 105° C. Memory cells with low activation energy defects may therefore be undetectable by this retention bake wafer test and result in devices failing the memory retention specifications in the field.

### SUMMARY

The data retention time of a non-volatile memory array containing multiple non-volatile memory cells, each cell having a floating gate, may be tested. The method may include: charging the floating gate of each memory cell; measuring the charge on the floating gate of each memory cell a first time; storing information indicative of the first-time measured charge on the floating gate of each memory cell; baking the non-volatile memory array at a first temperature for a first duration; measuring the charge on the floating gate of each memory cell a second time; storing information indicative of the second-time measured charge on the floating gate of each memory cell; baking the non-volatile memory array at a second temperature that is materially different than the first temperature for a second duration; measuring the charge on the floating gate of each memory cell a third time; and estimating the data retention time of each memory cell based on the first-time, second-time, and third-time measured charge on the floating gate of each memory cell.

The data retention time of a non-volatile memory array containing multiple non-volatile memory cells, each cell having a floating gate, may be tested. The method may include: baking the non-volatile memory array at a first temperature for a first duration and at a second temperature that is materially different than the first temperature for a second duration; testing the non-volatile memory array before and after each baking; and deciding whether to use or sell the tested non-volatile memory array based on results of the testing before and after each baking.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 illustrates an example of a temperature test for a non-volatile memory array.

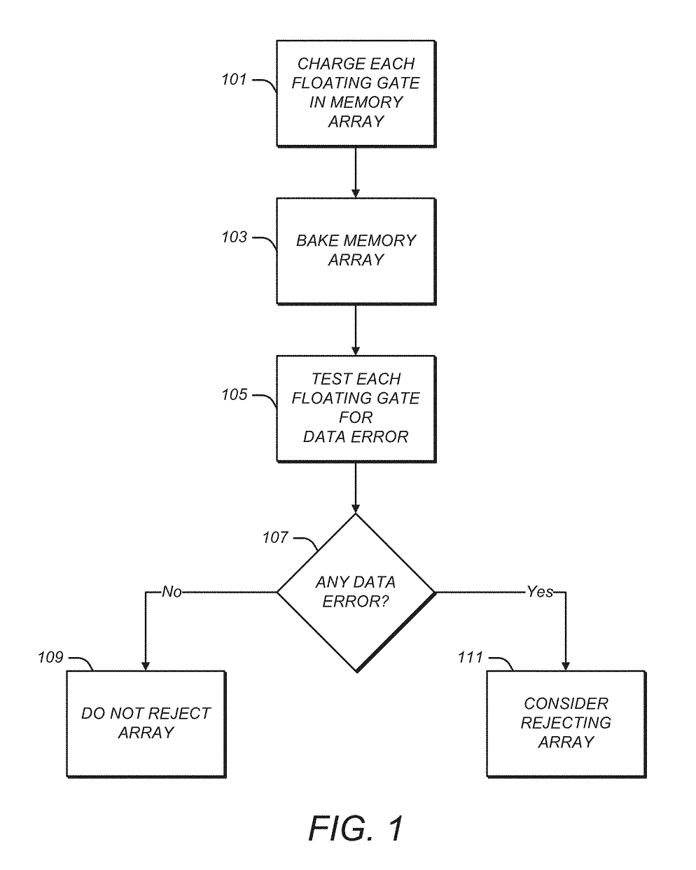

FIG. 2 illustrates an example of a multiple temperature test for a non-volatile memory array.

FIG. 3 illustrates an example of an activation energy and leak rate map for a large number of floating gates of a non-volatile memory array.

### DETAILED DESCRIPTION OF ILLUSTRATIVE EMBODIMENTS

Illustrative embodiments are now described. Other embodiments may be used in addition or instead. Details that may be apparent or unnecessary may be omitted to save space or for a more effective presentation. Some embodiments may be practiced with additional components or steps and/or without all of the components or steps that are described.

A method to production test the data retention time of every bit in a floating gate memory array that improves product quality with minimal impact on the production flow is now described. The test may measure the activation energy and rate of floating gate charge loss of each individual floating gate, and then calculate the expected time to failure of each cell at the data sheet conditions.

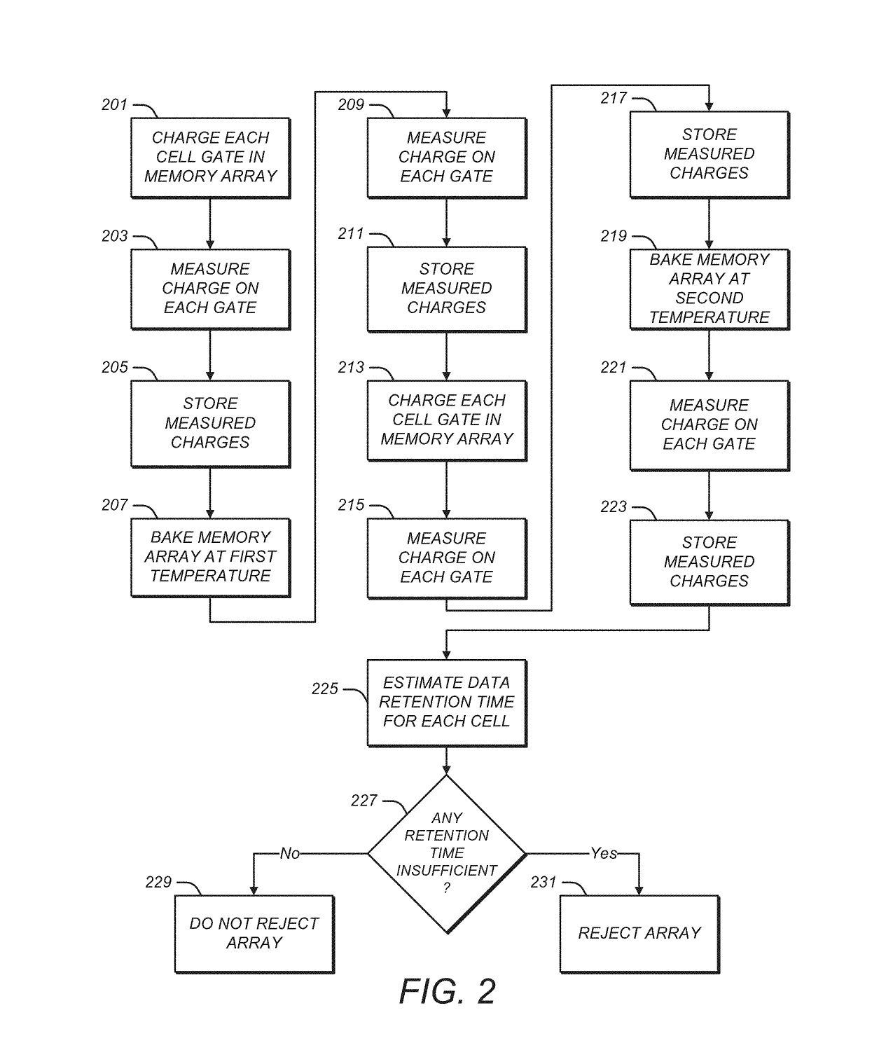

FIG. 2 illustrates an example of a multiple temperature test for a non-volatile memory array.

Each floating gate in the memory array may be charged, as reflected by a Charge Each Cell Gate in Memory Array step 201. During this step, the floating gates of each memory cell may be charged. For example a differential memory cell may be programmed in such a way to apply charge to both floating gates of the cell, in order to test the retention performance of each individual floating gate separately.

The charge on each floating gate may then be measured, as reflected by a Measure Charge on Each Gate step 203. This may be accomplished, for example, by measuring the current output of the MOS device with the charged floating gate.

Information indicative of the measured charge on each floating gate may then be stored in a data storage device in any form, such as in a file or a database, along with information identifying the cell having the measured charge, as reflected by a Store Measured Charges step 205.

The memory array may then be baked at a first temperature T₁ for a first baking time dt₁, as reflected by a Bake Memory Array at First Temperature step 207. This may be accomplished, for example, by baking the memory arrays in wafer form in inert atmosphere at 250° C. for 96 hours.

The first temperature T₁ may be at any level, such as within the range of 200° C. to 250° C.

The first baking time dt₁ may be of any length, such as between the range of 24 to 336 hours.

The charge on each floating gate may then be measured for a second time, as reflected by a Measure Charge on Each Gate step 209. The measuring may be done, for example, by any of the charge-measuring approaches discussed above.

Information indicative of the second measured charge on each floating gate may then be stored in a data storage device in any form, such as in any of the forms discussed above, along with information identifying the cell having the measured charge, as reflected by a Store Measured Charges step 211.

Each cell floating gate in the memory array may then be charged for a second time, as reflected by a Charge Each Cell Gate in Memory Array step 213. This may be accomplished, for example, by using any of the floating gate-charging methods discussed above.

The charge on each floating gate may then be measured for a third time, as reflected on by a Measure Charge on Each Gate step 215. The measuring may be done, for example, by any of the charge-measuring approaches discussed above.

Information indicative of the third measured charge on each floating gate may then be stored in a data storage device in any of the forms discussed above, along with information identifying the cell having the measured charge, as reflected by a Store Measured Charge step 217.

In some data retention time test methods, steps to 213-217 may be omitted.

Whether steps to 213-217 are taken or omitted, the memory array may then be baked at a second temperature T₂ for a second baking time dt₂, as reflected by a Bake Memory Array at Second Temperature step 219. This may be accomplished using any of the baking methods discussed above.

The second temperature T₂ may be at any level, such as within the range of 200° C. to 250° C. Notwithstanding, the second temperature T₂ may be materially different than the first temperature T₁ so as to cause the charge loss rate of the floating gates to be detectably different than the charge loss rate of the floating gates during the first bake step. This allows accurate extraction of the activation energy Eₐ

The first and second baking times dt1, and dt₂ may be the same or different. In practice, the duration of the bake with the lower temperature may be longer in order to produce charge loss that can be measured with high accuracy. For example T₁=250° C. for dt₁=96 hours and T₂=210° C. for dt₂=336 hours.

The charge on each floating gate may then be measured for a fourth time, as reflected on by a Measure Charge on Each Gate step 221. The measuring may be done, for example, by any of the charge-measuring approaches discussed above.

The non-volatile memory array may be part of a die on a wafer containing other dies, such as other dies that each contain another non-volatile memory array. The fourth time measuring may be done before or after the die containing the tested non-volatile memory array is separated from the other dies.

Information indicative of the fourth measured charge on each floating gate may then optionally be stored in the data storage device in any of the forms discussed above, along with information identifying the cell having the measured charge, as reflected by a Store Measured Charge step 223.

The multiple sets of floating gate charge measurements for the cells may then be used to calculate the activation energy and the rate of floating gate charge loss for each memory cell individually. This information may then be used to calculate an estimated time to failure at the guaranteed data sheet conditions, as reflected by an Estimate Data Retention Time for Each Cell step 225.

A determination may then be made as to whether any of the estimated data retention times are insufficient, as reflected by an Estimated Retention Time Insufficient decision step 227. If all of the times are sufficient, the memory array may not be rejected, as reflected by a Do Not Reject Array step 229. If a time is insufficient, on the other hand, the memory array may be rejected, as reflected by a Reject Array step 231. Rejection of a memory array may mean that it is not used or sold.

Even when a data retention time is below specification, however, the memory array may have error correction circuitry that may still allow the accurate data to be reproduced. In this situation, one or a few failing cells may not be deemed a sufficient reason to justify rejection of the array. On the other hand, if a large number of cells have an insufficient retention time, the array may still be rejected.

The two bakes at different temperatures may yield two different charge loss rates, and two separate time constants corresponding to the two temperatures T₁ and T₂ can be calculated as follows:

$$\begin{matrix}{τ}_{{T}_{2}} = {dt}_{1} \frac{{Q}_{FG 1}}{( {Q}_{FG 1} - {Q}_{FG 2} )} & ( 2 ) \\ {τ}_{{T}_{2}} = {dt}_{2} \frac{{Q}_{FG 3}}{( {Q}_{FG 3} - {Q}_{FG 4} )} & ( 3 )\end{matrix}$$

The floating gate charge can be measured using the cell current I_{FG} or the threshold voltage V_{TH} of the read device controlled by the floating gate. If the cell currents are used for measurements, the time constant can be approximated as:

$$\begin{matrix}{τ}_{{T}_{1}} = {dt}_{1} \frac{{I}_{1}}{( {I}_{1} - {I}_{2} )} & ( 4 ) \\ {τ}_{{T}_{2}} = {dt}_{2} \frac{{I}_{3}}{( {I}_{3} - {I}_{4} )} & ( 5 )\end{matrix}$$

The currents I₁, I₂, I₃, I₄ may be the floating gate cell currents measured at wafer sort, corresponding to the four cell measurement points from the test. Using the acceleration factor (1), the activation energy of each cell can be calculated from:

$$\begin{matrix}{τ}_{{T}_{2}} = {τ}_{{T}_{1}} {e}^{( \frac{{qE}_{a}}{k} ) ( \frac{1}{{T}_{2}} - \frac{1}{{T}_{1}} )} & ( 6 ) \\ {E}_{a} - ( \frac{k}{q} ) \frac{1}{( \frac{1}{{T}_{2}} - \frac{1}{{T}_{1}} )} log ( \frac{{τ}_{{T}_{2}}}{{τ}_{{T}_{1}}} ) & ( 7 )\end{matrix}$$

The time constant τ_{T}_{₀} at the datasheet temperature T₀ can be estimated using the calculated activation energy:

$${τ}_{{T}_{0}} = {τ}_{{T}_{2}} {e}^{( \frac{{qE}_{a}}{k} ) ( \frac{1}{{T}_{0}} - \frac{1}{{T}_{2}} )} \qquad ( 8 )$$

The time constant τ_{T}_{₀} can also be estimated using the data from the T₁ bake (equations (8) and (9) are mathematically equivalent, since Eₐ is calculated using only two bakes):

$${τ}_{{T}_{0}} = {τ}_{{T}_{1}} {e}^{( \frac{{qE}_{a}}{k} ) ( \frac{1}{{T}_{0}} - \frac{1}{{T}_{1}} )} \qquad ( 9 )$$

The time to failure TTF₀ at the temperature T₀ can be calculated from τ_{T}_{₀}:

TTF₀=γτ_{T}_{₀} (10)

The coefficient γ may take into account the design of the read amplifier, and may be a function of the program and the read threshold levels. It can also be used to add test margin by post-multiplying with the appropriate coefficient.

Detailed wafer maps with the activation energy and leak rate can be constructed with the per-cell data, which can allow quick identification of process problems. Mapping the results from each cell on the [1/τ_{T}_{₀},Eₐ] plane shows the correlation between the leak rate and activation energy of the different defects.

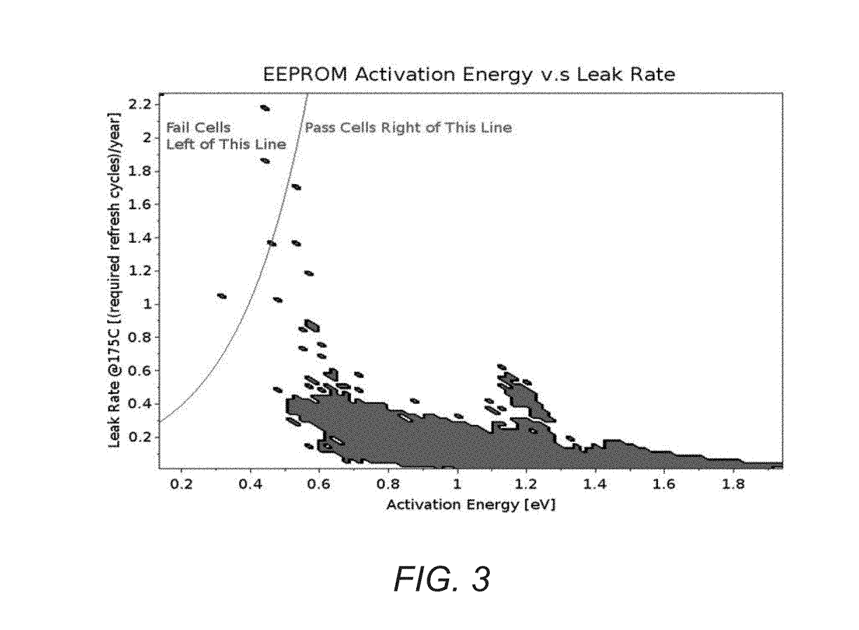

FIG. 3 illustrates an example of an activation energy and leak rate map for a large number of floating gates of a non-volatile memory array. Different defect types may form clusters in different locations. The worst defects may be the ones with low activation energy and high leak rates, since the low activation energy means that they cannot be screened with a short high-temperature bake, but the charge on the floating gate is dissipated quickly due to the high leak rate. The line in FIG. 3 shows the combination of activation energy and leak rate that corresponds to the specific data sheet guarantee (in this case 10 years at 105° C.).

The described test flow measures the rate of charge loss for each floating gate in the non-volatile memory at two different temperatures, and calculates the activation energy and the expected time-to-failure for each floating gate. This test flow allows identification of defective cells that are undetectable using the conventional single temperature bake test. The temperature of each memory array can optionally be measured individually, and the charge measurements can be corrected for any detected temperature variation in order to increase the overall accuracy of the estimation of the time to failure. This can be important due to the fact that the cell current measurement that is used to infer the floating gate charge of the MOS devices forming the floating gate memory array can be sensitive to the device temperature. The temperature measurements may be done in a controlled temperature environment.

The components, steps, features, objects, benefits, and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, objects, benefits, and/or advantages. These also include embodiments in which the components and/or steps are arranged and/or ordered differently.

For example, additional temperature-correction steps may be inserted during the measurements of the floating gate charge. Since the observable current drive of a MOS device with a charged floating gate is temperature-dependent, having the memory array tested at a well-controlled and accurate temperature increases the measurement accuracy, and therefore the accuracy of the time-to-failure estimation. An alternative approach would be to test at room temperature, measure the exact temperature of the memory array and then apply a correction factor taking into account the variation of the poorly controlled room temperature.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

All articles, patents, patent applications, and other publications that have been cited in this disclosure are incorporated herein by reference.

The phrase “means for” when used in a claim is intended to and should be interpreted to embrace the corresponding structures and materials that have been described and their equivalents. Similarly, the phrase “step for” when used in a claim is intended to and should be interpreted to embrace the corresponding acts that have been described and their equivalents. The absence of these phrases from a claim means that the claim is not intended to and should not be interpreted to be limited to these corresponding structures, materials, or acts, or to their equivalents.

The scope of protection is limited solely by the claims that now follow. That scope is intended and should be interpreted to be as broad as is consistent with the ordinary meaning of the language that is used in the claims when interpreted in light of this specification and the prosecution history that follows, except where specific meanings have been set forth, and to encompass all structural and functional equivalents.

Relational terms such as “first” and “second” and the like may be used solely to distinguish one entity or action from another, without necessarily requiring or implying any actual relationship or order between them. The terms “comprises,” “comprising,” and any other variation thereof when used in connection with a list of elements in the specification or claims are intended to indicate that the list is not exclusive and that other elements may be included. Similarly, an element proceeded by an “a” or an “an” does not, without further constraints, preclude the existence of additional elements of the identical type.

None of the claims are intended to embrace subject matter that fails to satisfy the requirement of Sections 101, 102, or 103 of the Patent Act, nor should they be interpreted in such a way. Any unintended coverage of such subject matter is hereby disclaimed. Except as just stated in this paragraph, nothing that has been stated or illustrated is intended or should be interpreted to cause a dedication of any component, step, feature, object, benefit, advantage, or equivalent to the public, regardless of whether it is or is not recited in the claims.

The abstract is provided to help the reader quickly ascertain the nature of the technical disclosure. It is submitted with the understanding that it will not be used to interpret or limit the scope or meaning of the claims. In addition, various features in the foregoing detailed description are grouped together in various embodiments to streamline the disclosure. This method of disclosure should not be interpreted as requiring claimed embodiments to require more features than are expressly recited in each claim. Rather, as the following claims reflect, inventive subject matter lies in less than all features of a single disclosed embodiment. Thus, the following claims are hereby incorporated into the detailed description, with each claim standing on its own as separately claimed subject matter.

1. A method of testing the data retention time of a non-volatile memory array containing multiple non-volatile memory cells, each cell having a floating gate, comprising in the order recited:
charging the floating gate of each memory cell;
measuring the charge on the floating gate of each memory cell a first time;
storing information indicative of the first-time measured charge on the floating gate of each memory cell;
baking the non-volatile memory array at a first temperature for a first duration;
measuring the charge on the floating gate of each memory cell a second time;
storing information indicative of the second-time measured charge on the floating gate of each memory cell;
baking the non-volatile memory array at a second temperature that is materially different than the first temperature for a second duration;
measuring the charge on the floating gate of each memory cell a third time; and
estimating the data retention time of each memory cell based on the first-time, second-time, and third-time measured charge on the floating gate of each memory cell.

2. The method of claim 1 further comprising, between the baking at the first and the second temperature, in the order recited:
charging the floating gate of each memory cell a second time;
measuring the charge on the floating gate of each memory cell after the second-time charging; and
storing information indicative of the measured charge on the floating gate of each memory cell after the second time charging,
wherein the estimating the data retention time of each memory cell is also based on the measured charge on the floating gate of each memory cell after the second time charging.

3. The method of claim 1 wherein:
the non-volatile memory array is part of a die on a wafer containing other dies; and
the third time measuring is done before the die containing the non-volatile memory array is separated from the other dies.

4. The method of claim 1 wherein:
the non-volatile memory array is part of a die on a wafer containing other dies; and
the third time measuring is done after the die containing the non-volatile memory array is separated from the other dies.

5. The method of claim 1 further comprising deciding whether to use or sell the tested non-volatile memory array based on the estimated data retention time of each memory cell.

6. The method of claim 1 further comprising measuring the temperature of the memory array and adjusting the charge measurements for any detected temperature variation.

7. The method of claim 6 wherein the temperature measurements are performed in a controlled temperature environment.

8. A method of testing the data retention time of a non-volatile memory array containing multiple non-volatile memory cells, each cell having a floating gate, comprising in the order recited:
charging the floating gate of each memory cell;
measuring the charge on the floating gate of each memory cell a first time;
storing information indicative of the first-time measured charge on the floating gate of each memory cell;
baking the non-volatile memory array at a first temperature for a first duration;
measuring the charge on the floating gate of each memory cell a second time;
storing information indicative of the second-time measured charge on the floating gate of each memory cell;
baking the non-volatile memory array at a second temperature that is materially different than the first temperature for a second duration;
measuring the charge on the floating gate of each memory cell a third time; and
deciding whether to use or sell the tested non-volatile memory array based on the first-time, second-time, and third-time measured charge on the floating gate of each memory cell.

9. The method of claim 8 further comprising, between the baking at the first and the second temperature, in the order recited:
charging the floating gate of each memory cell a second time;
measuring the charge on the floating gate of each memory cell after the second-time charging; and
storing information indicative of the measured charge on the floating gate of each memory cell after the second time charging,
wherein the deciding whether to use or sell is also based on the measured charge on the floating gate of each memory cell after the second time charging.

10. The method of claim 8 wherein:
the non-volatile memory array is part of a die on a wafer containing other dies; and
the third time measuring is done before the die containing the non-volatile memory array is separated from the other dies.

11. The method of claim 8 wherein:
the non-volatile memory array is part of a die on a wafer containing other dies; and
the third time measuring is done after the die containing the non-volatile memory array is separated from the other dies.

12. A method of testing the data retention time of a non-volatile memory array containing multiple non-volatile memory cells, each cell having a floating gate, comprising:
baking the non-volatile memory array at a first temperature for a first duration and at a second temperature that is materially different than the first temperature for a second duration;
testing the non-volatile memory array before and after each baking; and
deciding whether to use or sell the tested non-volatile memory array based on results of the testing before and after each baking.

13. The method of claim 12 wherein:
the non-volatile memory array is part of a die on a wafer containing other dies; and
all of the testing is done before the die containing the non-volatile memory array is separated from the other dies.

14. The method of claim 12 wherein:
the non-volatile memory array is part of a die on a wafer containing other dies; and
a part of the testing is done after the die containing the non-volatile memory array is separated from the other dies.

15. The method of claim 12 further comprising measuring the temperature of the memory array and adjusting the charge measurements for any detected temperature variation.

16. The method of claim 15 wherein the temperature measurements are performed in a controlled temperature environment.

17. The method of claim 1 wherein the first temperature is within the range of 200° C. and 250° C.

18. The method of claim 1 wherein the second temperature is within the range of 200° C. and 250° C.

19. The method of claim 1 wherein both the first and the second temperatures are within the range of 200° C. and 250° C.

20. The method of claim 8 wherein both the first and the second temperatures are within the range of 200° C. and 250° C.
